(19) United States
(12) Patent Application Publication
(10) Pub. No.: US 2024/0120355 A1
(43) Pub. Date: Apr. 11, 2024

(54) BLACK MASK ON GLASS SYSTEMS AND RELATED METHODS

(71) Applicant: SEMICONDUCTOR COMPONENTS INDUSTRIES, LLC, Scottsdale, AZ (US)

(72) Inventors: Gregg BARDEL, San Jose, CA (US); Shih-Chang TAI, Zhubei City (TW); Shunsuke YASUDA, Ora-Gun (JP); Weng-Jin WU, Hsinchu City (TW)

(73) Assignee: SEMICONDUCTOR COMPONENTS INDUSTRIES, LLC, Scottsdale, AZ (US)

(21) Appl. No.: 18/473,659

(22) Filed: Sep. 25, 2023

Related U.S. Application Data
(60) Provisional application No. 63/378,457, filed on Oct. 5, 2022.

(51) Int. Cl. H01L 27/146

(52) U.S. Cl. CPC H01L 27/14623; H01L 27/14685

(57) ABSTRACT

Implementations of a cover for an image sensor may include an optically transmissive portion and a black mask layer applied as a strip adjacent a perimeter of a largest planar surface of the optically transmissive portion. The first edge of the strip closest to the perimeter may be separated from the perimeter by a predetermined distance.

### CROSS REFERENCE TO RELATED APPLICATIONS

This document claims the benefit of the filing date of U.S. Provisional Patent Application 63/378,457, entitled “Black Mask On Glass Configurations” to Bardel et al. which was filed on Oct. 5, 2022, the disclosure of which is hereby incorporated entirely herein by reference.

### BACKGROUND

### 1. Technical Field

Aspects of this document relate generally to packages for semiconductor die, such as image sensor die.

### 2. Background

Semiconductor packages have been devised that permit routing of electrical signals from semiconductor die to a motherboard or other circuit board to which the semiconductor package is attached. Semiconductor packages also have been developed to protect semiconductor die from electrostatic discharge or humidity.

### SUMMARY

Implementations of a cover for an image sensor may include an optically transmissive portion and a black mask layer applied as a strip adjacent a perimeter of a largest planar surface of the optically transmissive portion. The first edge of the strip closest to the perimeter may be separated from the perimeter by a predetermined distance.

Implementations of a cover for an image sensor may include one, all, or any of the following:

The second edge of the strip closest to a center of the optically transmissive portion may be configured to overhang a set of bond pads of a substrate a predetermined distance when the optically transmissive portion may be coupled over the substrate.

The width of the strip between the first edge and a second edge may be constant around the strip.

The width of the strip between the first edge and a second edge may be the same for at least two portions of the strip applied adjacent two sides of the optically transmissive portion.

The first edge of the strip closest to the perimeter may be separated from the perimeter only at portions of the perimeter not enclosed with a circle drawn at a predetermined location within the optically transmissive portion.

Within the circle, the first edge of the strip may reach the perimeter.

The cover may include corner regions of the black mask layer inset into a material of the black mask layer beyond the predetermined distance.

Implementations of a cover for an image sensor may include an optically transmissive portion and a black mask layer applied as a strip around a perimeter of a largest planar surface of the optically transmissive portion and including corner regions of the black mask layer inset into a material of the black mask layer.

Implementations of a cover for an image sensor may include one, all, or any of the following:

The first edge of the strip closest to the perimeter may be pulled back from the perimeter.

The second edge of the strip closest to a center of the optically transmissive portion may be configured to overhang a set of bond pads of a substrate a predetermined distance when the optically transmissive portion may be coupled over the substrate.

The width of the strip between the first edge and the second edge may be constant around the strip.

The width of the strip between the first edge and the second edge may be the same for at least two portions of the strip applied adjacent two sides of the optically transmissive portion.

The first edge of the strip closest to the perimeter may be separated from the perimeter only at portions of the perimeter not enclosed with a circle drawn at a predetermined location within the optically transmissive portion.

Within the circle, the first edge of the strip may reach the perimeter.

Implementations of a method of controlling the height of an adhesive material may include providing an optically transmissive cover and an image sensor die; applying an adhesive material adjacent a perimeter of the image sensor die; contacting and pressing the optically transmissive cover into the adhesive material to a first height; drawing the adhesive material to a desired second height above the image sensor die with the optically transmissive cover; and releasing the optically transmissive cover.

Implementations of a method of controlling the height of an adhesive material may include one, all, or any of the following:

The method may include a black mask layer applied as a strip around a perimeter of a largest planar surface of the optically transmissive cover.

The first height may be below the second height.

The first height may be below an initial height of the adhesive material above the image sensor die.

The method may include creating uniform bondability between the optically transmissive cover and the adhesive material through the pressing and the drawing of the adhesive material.

Providing the optically transmissive cover and the image sensor die further may include providing a plurality of bond pads, bond wires, and wirebonds and wherein applying the adhesive material further may include applying the adhesive material over the plurality of bond pads, bond wires, and wirebonds.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a top view of an implementation of an optically transmissive cover coupled over an image sensor die and a substrate and a side view of the optically transmissive cover thereof;

FIG. 2 is a side view of an implementation of an image sensor die coupled to a substrate;

FIG. 3 is a side view of the implementation of the image sensor die coupled to the substrate of FIG. 2 following a wirebonding process;

FIG. 4 is a side view of the implementation of the image sensor die of FIG. 3 following coupling of an optically transmissive cover thereto;

FIG. 5 is a side view of the implementation of the image sensor die of FIG. 4 following an encapsulation process;

FIG. 6 is a top view of an implementation of an optically transmissive cover;

FIG. 7 is a top view of an implementation of an optically transmissive cover;

FIG. 8 is a top view of an implementation of an optically transmissive cover;

FIG. 9 is a top view of an implementation of an optically transmissive cover;

FIG. 10 is a top view of an implementation of an optically transmissive cover;

FIG. 11 is a top view of an implementation of an optically transmissive cover;

FIG. 12 is a side view of an implementation of an optically transmissive cover prior to being dropped onto adhesive material;

FIG. 13 is a side view of an implementation of an optically transmissive cover following being dropped onto adhesive material;

FIG. 14 is a side view of an implementation of an optically transmissive cover following contacting adhesive material;

FIG. 15 is a side view of the implementation of the optically transmissive cover of FIG. 14 following pressing into the adhesive material; and

FIG. 16 is a side view of the implementation of the optically transmissive cover of FIG. 16 following drawing of the adhesive material.

### DESCRIPTION

This disclosure, its aspects and implementations, are not limited to the specific components, assembly procedures or method elements disclosed herein. Many additional components, assembly procedures and/or method elements known in the art consistent with the intended covers for image sensors and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such covers for image sensors, and implementing components and methods, consistent with the intended operation and methods.

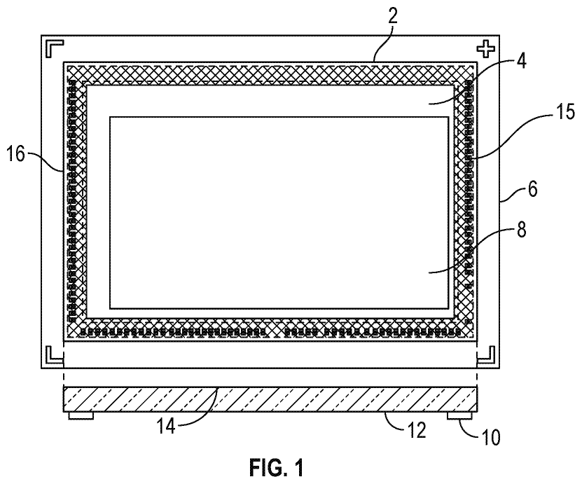

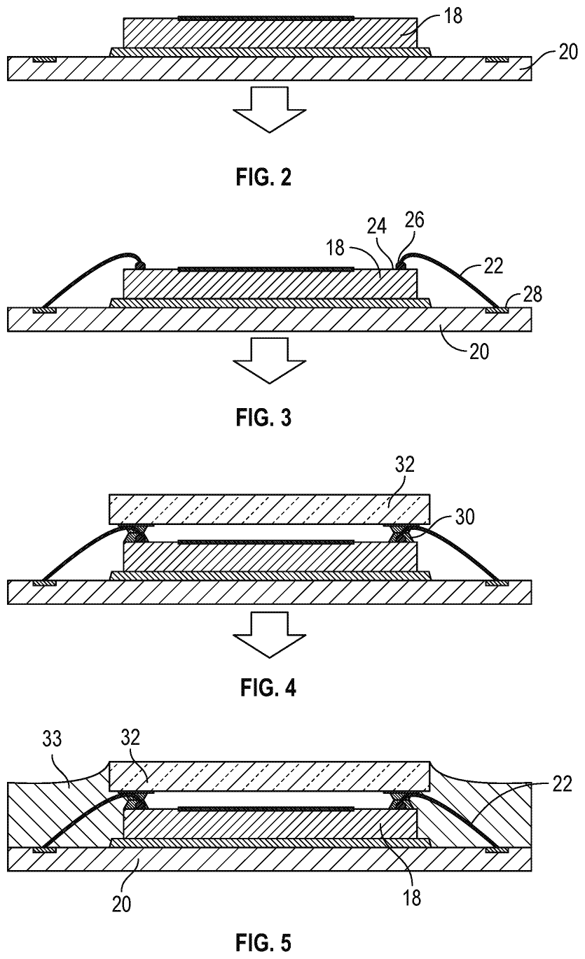

Referring to FIG. 1, an implementation of an optically transmissive cover (cover for an image sensor) 2 is illustrated coupled over image sensor die 4 which is coupled to substrate 6. The image sensor 4 includes pixel array 8 which is visible through the material of the optically transmissive cover 2. In the side view in FIG. 2, the optically transmissive cover 2 is illustrated with a black mask layer (black mask) 10 coupled to a largest planar surface 12 of the optically transmissive cover 2. While in the implementation illustrated in FIG. 1 the black mask 10 is attached to the largest planar surface 12 that faces the pixel array 8, in other implementations, the black mask 10 could be attached to the largest planar surface 14 that faces away from the pixel array 8.

In the view of FIG. 1, a plurality of bond pads 15 are visible through the optically transmissive cover 2. These bond pads 15 have wirebonds formed thereto with bond wires (not shown in FIG. 1) that permit routing of electrical signals from the image sensor die 4 to the substrate 6. As visible in FIG. 1, the pixel array 8 is not centered within the perimeter 16 of the optically transmissive cover 2 for the image sensor die 4 of FIG. 1. The materials of the optically transmissive cover implementations disclosed in this document may include any of a wide variety of materials, including, by non-limiting example, glass, plastic, polymers, calcite, quartz, or any other material capable of transmitting the particular wavelength of electromagnetic radiation the pixel array is designed to receive. The various image sensor packages disclosed herein may be used to detect electromagnetic radiation of any of a wide variety of wavelengths, including, by non-limiting example, infrared, visible, ultraviolet, x-ray, or any other wavelength.

The various optically transmissive cover implementations disclosed herein may be utilized in various image sensor package designs and methods of making such image sensor packages. Referring to FIG. 2, an implementation of an image sensor die (image sensor) 18 bonded to substrate 20 is illustrated. FIG. 3 illustrates the image sensor 18 following a wirebonding process where bond wires 22 are bonded to bond pads 24 on image sensor 18 to for wirebonds 26 and pads 28 on substrate 20. Following wirebonding, an adhesive material 30 is applied over the wirebonds 26 and pads 28 on the image sensor 18 and then optically transmissive cover 32 is coupled to the adhesive material 30 forming a package like that illustrated in FIG. 4 Various curing processes can be employed in various method implementations to help form the bond between the adhesive material 30 and the optically transmissive cover 32 including, by non-limiting example, exposure to electromagnetic radiation, exposure to ultraviolet light, heating (thermal curing), exposure to both electromagnetic radiation and heating, or any combination thereof. The particular process used depends on the material type used for the adhesive material which may be, by non-limiting example, an epoxy, a resin, a glass-attach epoxy, or any other adhesive type capable of bonding the material of the optically transmissive cover to the image sensor die.

This particular image sensor design illustrated in FIG. 4 is referred to as a wire-in-dam package. However, other image sensor package designs could be employed in various implementations, including those where the optically transmissive cover is bonded to the die on either side of the bond pads or the optically transmissive cover is bonded to the substrate itself directly. Also, while the image sensor packages illustrated in FIGS. 2-5 include an air gap, the various system and method implementations disclosed herein could be employed with both gapped and gapless image sensor package designs.

Referring to FIG. 5, the image sensor die 18 is illustrated following application of encapsulant/mold compound 33 around the image sensor die 18, the bond wires 22, the optically transmissive cover 32 and over the substrate 20. At this point, the image sensor package is ready for final processing steps prior to being coupled with a circuit board or other motherboard.

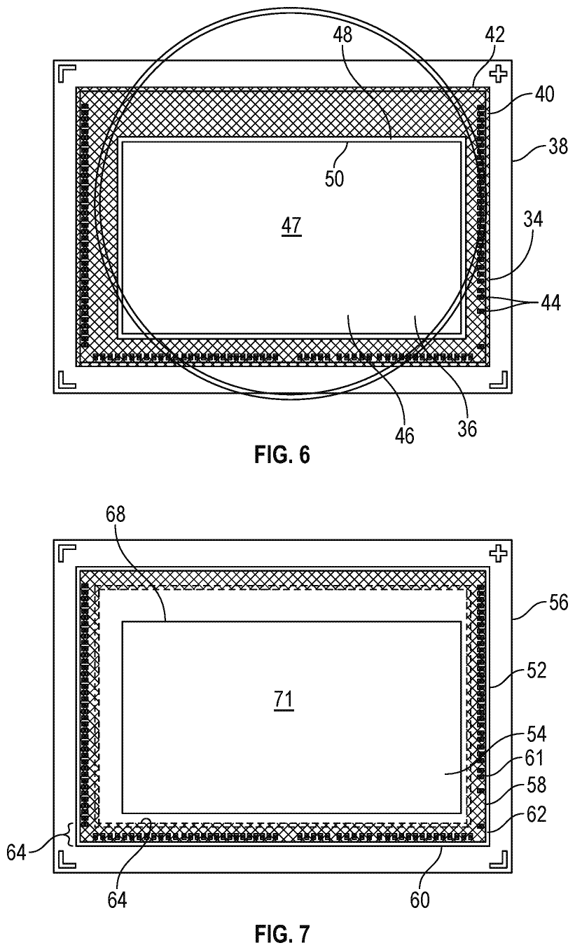

Various implementations of black masks are disclosed in this document. While specific implementations are illustrated in the figures, it must be understood that these merely are illustrative of the principles disclosed herein and so various combinations of these principles may be utilized in various implementations. One of the challenges presented by the use of black masks is that the black mask material interferes with any electromagnetic curing process used to completely or partially cure the adhesive material because it shadows the material at least partially. Referring to FIG. 6, an implementation of an optically transmissive cover 34 is illustrated which is coupled over image sensor 36 which has been bonded to substrate 38. In this implementation, black mask 40 is illustrated, visible through the material of the optically transmissive cover 34, which comes out to/is coextensive with the perimeter 42 of the optically transmissive cover 34. In this implementation, the black mask 40 will fully shadow the adhesive material (not shown in FIG. 6) applied over the plurality of bond pads 44. Because the adhesive material is fully shadowed from electromagnetic radiation that irradiates the adhesive material from the direct top-down direction (into the paper in FIG. 6), the ability to achieve a desired initial cure of the adhesive material with the electromagnetic radiation can be difficult or impossible to achieve. Furthermore, the incomplete cure of the adhesive material using the electromagnetic radiation can result in incomplete curing of the adhesive material even after a thermal curing step, causing corrosion of the bond pads/wirebonds due to migration of ionic contaminants (like chlorine) in the incompletely cured adhesive material during operation of the image sensor.

In the implementation illustrated in FIG. 6, the edge 48 of the black mask 40 closest to the pixel array 47 comes up almost to the edge 50 of the pixel array 47 (overhangs the image sensor 46) except for a short separation distance. This overhang of the black mask 40 may permit as much blocking of any scattered light as possible to help with reducing/eliminating flare and other defects in the resulting images from the pixel array.

Referring to FIG. 7, another implementation of an optically transmissive cover 52 coupled over image sensor 54 bonded to substrate 56 is illustrated. Here, black mask 58 is illustrated through the material of the optically transmissive cover 52. The black mask 58 takes the form of a strip of material that has been coupled around/applied around/adjacent to the perimeter 60 of the optically transmissive cover 52. The shape of the strip of the black mask 58 here forms a rectangle. As illustrated, the edge (first edge) 61 of the black mask 58 that is closest to the perimeter 60 of the optically transmissive cover 52 is separated from the perimeter 60 by a predetermined distance 62. Put differently, the material/edge 61 of the black mask 58 has been pulled back from the perimeter 60 to the predetermined distance 62.

In FIG. 7, the location of the edge 64 (second edge) of the black mask 58 that is closest to the center of the optically transmissive cover (portion) 52 is set to overhang the image sensor 54, but at a fixed width keeping the width 66 of the strip the same on all four sides of the black mask 58. In comparison with the edge 68 of the pixel array 71, the constant overhang results in different distances between the edge 64 and the edge 68 of the pixel array 71 because the pixel array 71 is not centered within the perimeter of the optically transmissive cover 52.

The effect of the pull back or predetermined distance 62 is that the adhesive material is not fully shadowed by the black mask 58 in this area. Furthermore, because the electromagnetic radiation sources used in the electromagnetic radiation curing steps are often diffuse light sources, the predetermined distance 62 may result in a wider actual area of irradiation into the adhesive material that just the actual width of the predetermined distance 62. This has the effect of increasing the cure of the bulk of the adhesive material overall. The wider the predetermined distance, the less shadowing of the adhesive material. The tradeoff for wider predetermined distances is that a higher probability exists for reflecting/scattering of light from the surfaces of the bond pads/wirebonds also exposed to ambient light during operation of the image sensor package.

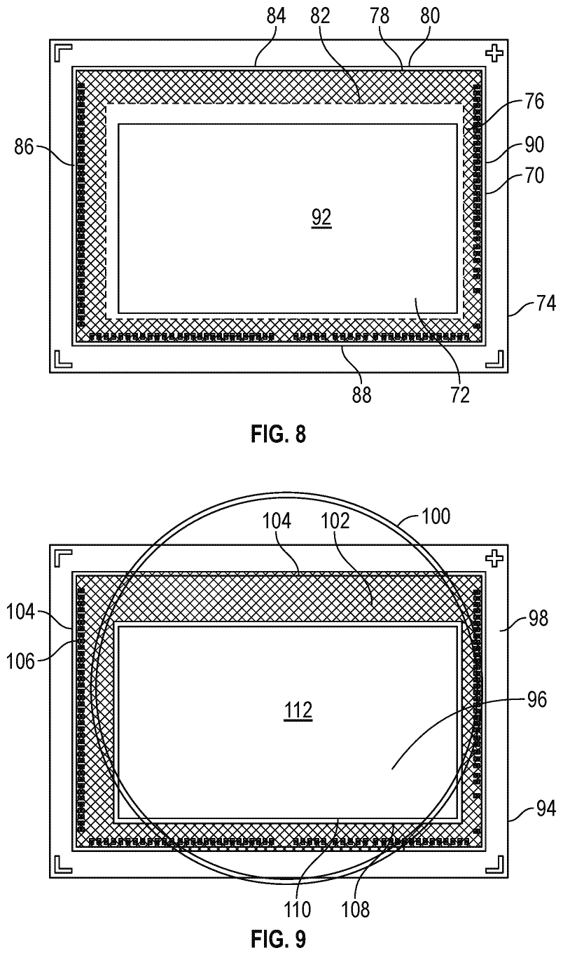

The overhang of the black mask can be varied in various optically transmissive cover implementations. Referring to FIG. 8, another implementation of an optically transmissive cover 70 is illustrated coupled over image sensor 72 bonded to substrate 74. Here the black mask 76 includes edge 78 that is pulled back from the perimeter 80 of the optically transmissive cover 70 a predetermined distance that is uniform around the perimeter 80. However, the overhang, or the location of edge 82 of the black mask 76 varies in the implementation illustrated in FIG. 8, creating a strip that is wider on sides 84, 86 of the optically transmissive cover 70 than on sides 88, 90. By inspection, the width of the strip of the black mask 76 is the same for side 88, 90 but not the same for sides 84, 86. In this implementation, the ability to increase the overhang to a desired amount may help with reducing scattered light impacting the pixel array 92 and causing flare.

Referring to FIG. 9, another implementation of an optically transmissive cover 94 is illustrated coupled over image sensor 96 bonded to substrate 98. Shown in FIG. 9 is circle 100 which does not physically appear on the optically transmissive cover 94 itself, but is included as a guide to show how the pattern of black mask 102 is laid out on the optically transmissive cover 94. By inspection, the portions of the black mask 102 that are within the circle 100 have an edge that reaches the perimeter 104 of the optically transmissive cover 94. The portions of the black mask 102 that outside the circle have a pullback that sets the edge 106 of the black mask 102 a predetermined distance separated from the perimeter 104. The predetermined distance in this implementation is constant outside the circle, but in other implementations, the predetermined distance can be varied. While in this implementation, the area inside the circle has the black mask reaching the perimeter while the areas outside the circle include the pullback, in other implementations, the reverse situation may be used.

In the implementation of FIG. 9, the overhang set by the edge 108 creates a constant width/distance between the edge 108 and the edge 110 of the pixel array 112. While this is illustrated in FIG. 9, the overhang in various other optically transmissive cover implementations may be set to have a constant width of the strip of black mask 102, or a varying width that does not result in a constant between the edge 108 and the edge 110 as illustrated in FIGS. 7 and 8.

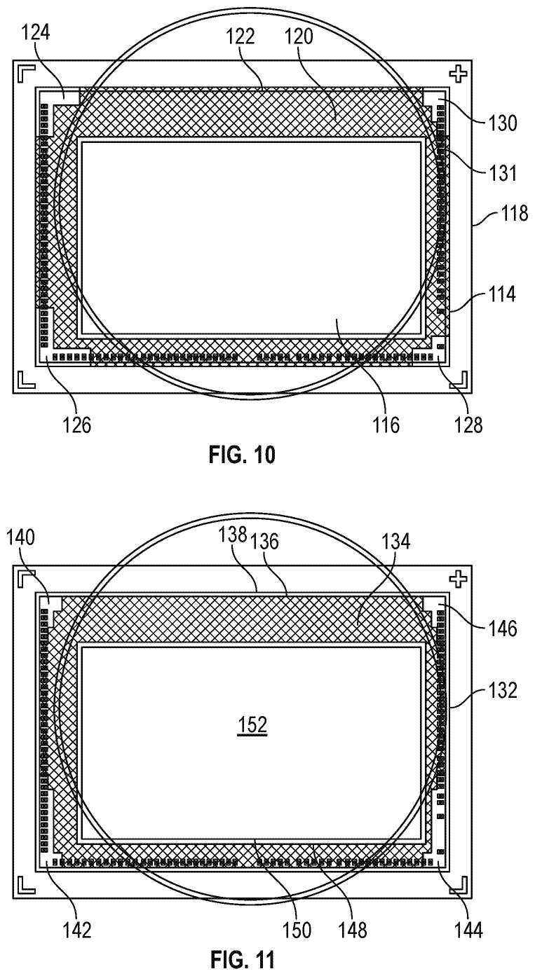

Referring to FIG. 10, another implementation of an optically transmissive cover 114 is illustrated that is coupled over image sensor 116 bonded to substrate 118. The circle in this figure is for reference, similar to the circle of FIG. 9. In this implementation, the edge of the black mask 120 reaches the perimeter 122 of the substrate 118 and only corner regions 124, 126, 128, 130 are inset into the material of the black mask 120, leaving the bond pads 131 below these areas exposed. In such implementations, the particular size and shape of these corner regions is determined by the desired electromagnetic radiation cure over the exposed bond pads (and immediately adjacent bond pads). In this way, the negative effects of corrosion over a high voltage bond pad(s), for example, located in one of the corner regions could be reduced/eliminated by ensuring no blocking by the black mask 120.

The use of corner regions like those illustrated in FIG. 10 can be combined with the other implementations disclosed herein. For example, as illustrated in FIG. 11, an implementation of an optically transmissive cover 132 is illustrated that has a black mask 134 that is pulled back to set the edge 136 at a constant distance away from the perimeter 138 all the way around the perimeter 138 except at corner regions 140, 142, 144, 146 which are inset into the material the black mask 134 at a predetermined distance and size. In this implementation, the overhang by the edge 148 of the black mask 134 is set to create a constant distance between the edge 148 and the edge 150 of the pixel array 152. However, in other implementations, any overhang disclosed herein may be used. A wide variety of implementations of black masks and optically transmissive covers combining the various principles disclosed herein may be constructed using the principles disclosed herein. The circle in FIG. 11 is included for reference similar to the circle of FIG. 9.

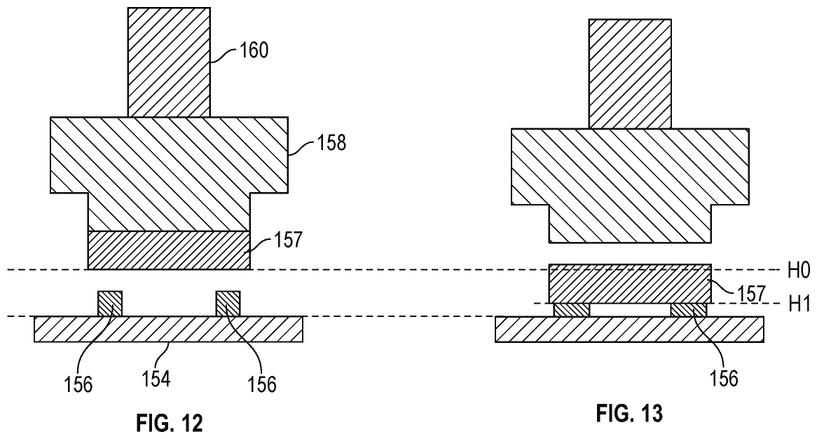

Referring to FIG. 12, an implementation of an image sensor 154 is illustrated with adhesive material 156 applied thereto around a perimeter of the image sensor 154. Oriented above the image sensor 154 is optically transmissive cover 157 which is held in place using the rubber tip 158 of collet 160. When the optically transmissive cover 157 is oriented above the image sensor 154 at the desired location in X and Y, the vacuum on the rubber tip 158 is released, causing the optically transmissive cover 157 to drop under gravity force through the air until it contacts adhesive material 156 (free air drop). FIG. 13 shows the resulting position of the optically transmissive cover 157 and the position of the adhesive material 156 which is observed to have spread under the weight/impact of the optically transmissive cover 157, causing the height of the adhesive material 156 to drop to H1 from H0 illustrated in FIG. 13. One of the challenges presented by the free air drop process is that voids can form in the adhesive material 156 as the optically transmissive cover 157 contacts it in free fall which remain once the optically transmissive cover reaches a rest position. These voids can cause delamination of the optically transmissive cover and/or reduce the shear force of separation between the adhesive material and the material of the optically transmissive cover. With the air drop process issues of liquid encapsulation sealing (LES) intrusion, compound body holes, glass (cover) tilt, and delamination following reliability testing or surface mounting processes for the image sensor package have been noted.

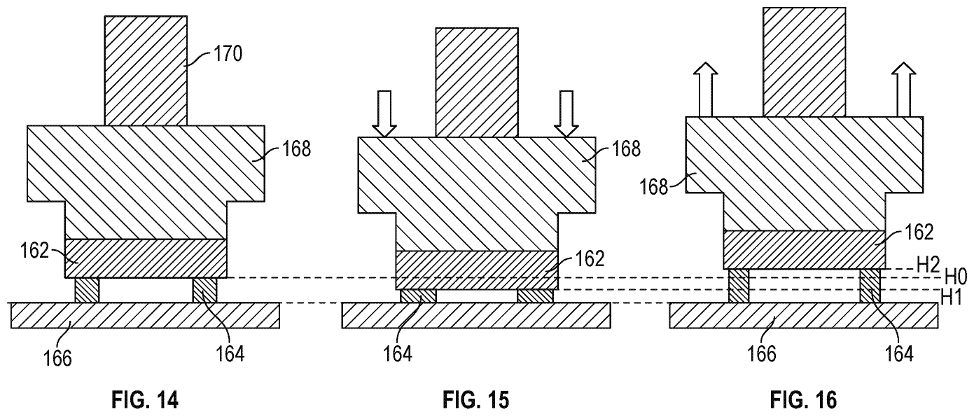

Referring to FIG. 14, an implementation of an optically transmissive cover 162 is illustrated following being placed directly in contact with adhesive material 164 coupled to image sensor die 166 by rubber tip 168 of collet 170. As illustrated, at this point in the process, the height of the adhesive material 164 is at H0. FIG. 15 illustrates the optically transmissive cover 162 following pressing of the optically transmissive cover 162 against to the adhesive material 164 with the rubber tip 168, resulting in the height of the adhesive material 164 being reduced to H1. Here H1 is below H0. Referring to FIG. 16, the optically transmissive cover 162 is illustrated following drawing of the adhesive material 164 coupled to the optically transmissive cover 162 through retracting the rubber tip 168 (while the vacuum is still on) to height H2. Here, H2 is higher than H0 and H1. Because of the ability to set the ultimate height of the adhesive material 164 following an initial pressing step by drawing the adhesive material 164 to the desired height, several benefits can be observed. These may include precise height control of the final height of the adhesive material above the surface of the image sensor die 166, uniform bondability between the adhesive material and the material of the optically transmissive cover 162, better shear force, avoidance of compound body holes, avoidance of delamination, reduction of LES intrusion, and/or reduction of voids in the adhesive. In a particular implementation, the H0 height was 400 microns, H1 was 310 microns, and H2 was 360 microns.

The various method implementations may include providing an optically transmissive cover and an image sensor die, applying an adhesive material adjacent the perimeter of the image sensor die, and contacting and pressing the optically transmissive cover into the adhesive material to a first height. The method may also include drawing the adhesive material to a desired second height above the image sensor die with the optically transmissive cover and releasing the optically transmissive cover from the rubber tip. These method implementations disclosed herein used to couple optically transmissive covers may be used with any optically transmissive cover type disclosed herein and with any image sensor package type disclosed herein. This includes wire-in-dam packages where the adhesive material is applied over wirebonds, bond pads, and bond wires as disclosed herein.

In places where the description above refers to particular implementations of optically transmissive covers and implementing components, sub-components, methods and sub-methods, it should be readily apparent that a number of modifications may be made without departing from the spirit thereof and that these implementations, implementing components, sub-components, methods and sub-methods may be applied to other optically transmissive covers.

What is claimed is:

1. A cover for an image sensor comprising:
an optically transmissive portion; and
a black mask layer applied as a strip adjacent a perimeter of a largest planar surface of the optically transmissive portion;
wherein a first edge of the strip closest to the perimeter is separated from the perimeter by a predetermined distance.

2. The cover of claim 1, wherein a second edge of the strip closest to a center of the optically transmissive portion is configured to overhang a set of bond pads of a substrate a predetermined distance when the optically transmissive portion is coupled over the substrate.

3. The cover of claim 1, wherein a width of the strip between the first edge and a second edge is constant around the strip.

4. The cover of claim 1, wherein a width of the strip between the first edge and a second edge is the same for at least two portions of the strip applied adjacent two sides of the optically transmissive portion.

5. The cover of claim 1, wherein the first edge of the strip closest to the perimeter is separated from the perimeter only at portions of the perimeter not enclosed with a circle drawn at a predetermined location within the optically transmissive portion.

6. The cover of claim 5, wherein within the circle, the first edge of the strip reaches the perimeter.

7. The cover of claim 1, further comprising corner regions of the black mask layer inset into a material of the black mask layer beyond the predetermined distance.

8. A cover for an image sensor comprising:
an optically transmissive portion; and
a black mask layer applied as a strip around a perimeter of a largest planar surface of the optically transmissive portion and comprising corner regions of the black mask layer inset into a material of the black mask layer.

9. The cover of claim 8, wherein a first edge of the strip closest to the perimeter is pulled back from the perimeter.

10. The cover of claim 9, wherein a second edge of the strip closest to a center of the optically transmissive portion is configured to overhang a set of bond pads of a substrate a predetermined distance when the optically transmissive portion is coupled over the substrate.

11. The cover of claim 10, wherein a width of the strip between the first edge and the second edge is constant around the strip.

12. The cover of claim 10, wherein a width of the strip between the first edge and the second edge is the same for at least two portions of the strip applied adjacent two sides of the optically transmissive portion.

13. The cover of claim 9, wherein a first edge of the strip closest to the perimeter is separated from the perimeter only at portions of the perimeter not enclosed with a circle drawn at a predetermined location within the optically transmissive portion.

14. The cover of claim 13, wherein within the circle, the first edge of the strip reaches the perimeter.

15. A method of controlling the height of an adhesive material, the method comprising:
providing an optically transmissive cover and an image sensor die;
applying an adhesive material adjacent a perimeter of the image sensor die;
contacting and pressing the optically transmissive cover into the adhesive material to a first height;
drawing the adhesive material to a desired second height above the image sensor die with the optically transmissive cover; and
releasing the optically transmissive cover.

16. The method of claim 15, further comprising a black mask layer applied as a strip around a perimeter of a largest planar surface of the optically transmissive cover.

17. The method of claim 15, wherein the first height is below the second height.

18. The method of claim 15, wherein the first height is below an initial height of the adhesive material above the image sensor die.

19. The method of claim 15, further comprising creating uniform bondability between the optically transmissive cover and the adhesive material through the pressing and the drawing of the adhesive material.

20. The method of claim 15, wherein providing the optically transmissive cover and the image sensor die further comprises providing a plurality of bond pads, bond wires, and wirebonds and wherein applying the adhesive material further comprises applying the adhesive material over the plurality of bond pads, bond wires, and wirebonds.
